(19) United States
(12) Patent Application Publication
(10) Pub. No.: US 2006/0223220 A1
(43) Pub. Date: Oct. 5, 2006

(54) Methods and structures to form precisely aligned stacks of 3-dimensional stacks with high resolution vertical interconnect

(76) Inventor: Robert W. Bower, Haiku, HI (US)

Correspondence Address: JOHN P. O'BANION;O'BANION & RITCHEY LLP, 400 CAPITOL MALL SUITE 1550, SACRAMENTO, CA, 95814, US

(21) Appl. No.: 11/356,717

(22) Filed: Feb. 17, 2006

Related U.S. Application Data
(60) Provisional application No. 60/654,248, filed on Feb. 18, 2005.

(51) Int. Cl. H01L 51/40

(52) U.S. Cl. 438/99

(57) ABSTRACT

Methods and structures to form precisely aligned stacks of 3-dimensional stacks with high resolution vertical interconnections, and associated stacks, structures and devices. Viewing ports are formed in a first nanostructure layer through which an alignment pattern on-a second nanostructure layer is visible when the first and second nanostructure layers are held in near contact before attachment. The second nanostructure layer is then aligned with the first nanostructure layer by viewing the alignment pattern through the viewing ports. Once the layers are aligned, the second nanostructure layer is attached to the first nanostructure layer.

### CROSS-REFERENCE TO RELATED APPLICATIONS

This application claims priority from U.S. provisional patent application serial number 60/654,248 filed on Feb. 18, 2005, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to fabrication of nanodevices, and more particularly to alignment of layers of nanostructures and fabrication of stacks, structures and devices.

2. Description of Related Art

Generally, alignment and bonding of stacks requires holding two rather thick structures, call them Structure A and Structure B, in near contact with their high density intricate features facing each other. It is desired to align these intricate features and then bond or otherwise attach the structures together. Finally, after bonding or attachment of the structures, a thinning process is used to thin one of the layers. Each structure may be a wafer, a portion of a wafer, or a chip. The problem is that generally the thick structures are opaque to the short wavelength visible or ultraviolet light that is needed to image and adjust the two faces into precise alignment. Since the two faces to be bonded or otherwise attached are obscured from direct observation with the desired wavelength of short wavelength visible or ultraviolet light, only crude alignment is possible with long wavelength light that penetrates the thick structures or use physical features on the exposed surfaces of the structures that also results in crude alignment. Such crude alignment of greater than plus or minus one micron does not allow the complexity potentially available in high density structures formed on the two surfaces to be realized in the bonded or otherwise attached 3-dimensional structures. These problems are illustrated in FIG. 1. In FIG. 1A, the detailed features of the bottom of the existing stack or handle 1 including vertical interconnects and device structures must be aligned to the corresponding detailed features of the top of the new layer 2 of nanostructure before this new layer has been thinned. In FIG. 1B, only crude alignment is achieved using IR (Infrared) light 3 passed through either of the comparatively thick structures blocking the detailed structures to be aligned or using “Edge Features” 4 to align, or using “Look Between Light Probes” 5 to align.

### BRIEF SUMMARY OF THE INVENTION

The present invention generally comprises methods for aligning layers of nanostructures, and fabrication of stacks, structures and devices, as well as the stacks, structures and devices fabricated therefrom. In the context of the present invention, the term “nanostructure” is used in the manner commonly used in the field of integrated circuits. The term “microstructures” was used in the field when features were greater than 1 μm, and the term “nanostructures” came into use when feature sizes became smaller than 1 μm. It will be appreciated, however, that the invention is not limited in its application to structures having features of a particular size classification.

In one embodiment, a general method for forming a stack of nanostructure layers involves forming a plurality of viewing ports in a first nanostructure layer through which an alignment pattern on a second nanostructure layer is visible when the first and second nanostructure layers are held in near contact before attachment, aligning the second nanostructure layer with the first nanostructure layer by viewing the alignment pattern through the viewing ports, and attaching the second nanostructure layer to the first nanostructure layer after alignment with the first nanostructure. In another embodiment, the foregoing method is expanded by extending the viewing ports through the attached second nanostructure layer, aligning a third nanostructure layer with the second nanostructure layer by viewing an alignment pattern on the third nanostructure layer through the extended viewing ports, and attaching the aligned third nanostructure layer to the second nanostructure layer.

In one embodiment, the alignment patterns are viewed under short wavelengths of visible ultraviolet light. In another embodiment, the viewing ports allow imaging of submicron alignment features. In a further embodiment, the layers are attached using an attachment method such as fusion bonding, low temperature fusion bonding, low temperature plasma assisted fusion bonding, adhesive bonding, anodic bonding, and thermal compression metal to metal bonding. In a still further embodiment, precision alignment features are included in each layer that are precisely aligned to the nanostructure of the layer with feature sizes and alignment that is that of the nanostructure itself.

In various embodiments, the nanostructure layers comprise a material selected from the group consisting essentially of Si, Ge, GaAs, Strained Si, Si-Ge, Fe compounds and other materials. On other various embodiments, intervening layers of heat sinks, RF shields, or various control function circuits needed to control the proper operation of a stacked system of nanostructure layers are interspersed throughout the stack and each layer with viewing ports that allow the optical viewing ports to extend through the layers and allow the layers to be precision aligned to the nanostructures in the stack.

The foregoing methods can further be expanded by, for example, thinning each nanostructure layer added to the stack using any method of thinning a processed nanostructure layer. In addition, in various embodiments at least one nanostructure layer can include extended viewing regions comprising embedded alignment features in a SiO₂ layer. In one such embodiment, the SiO₂ layer is compatible with the temperature constraints of the nanostructure layer.

The foregoing methods can also be expanded by, after attaching an added nanostructure layer, thinning the added nanostructure layer to leave (a) the nanostructure layer, and (b) connection features between the added layer and previous layers.

In other embodiments, the viewing ports form an extended optical pathway that is empty except for alignment features. In various embodiments, the viewing ports comprise holes. In other embodiments, the viewing ports comprise optical pathways. In such embodiments, the optical pathways are empty.

In further embodiments, the alignment pattern comprises alignment features are tethered to structures adjacent to optical pathways formed by the viewing ports. In still further embodiments, alignment features in optical pathways formed by the viewing ports can pass very short wavelengths of light that will not pass through SiO₂ or other solid materials. In various such embodiments, the optical pathways formed by the viewing ports will pass x-rays.

In another embodiment, the general method for forming a stack of nanostructure layers further involves providing a base layer, forming a set of viewing ports in the base layer, attaching the first nanostructure layer to the base layer, thinning said first nanostructure layer, and extending said viewing ports through said first nanostructure layer.

In another embodiment, each nanostructure layer to be aligned with the first nanostructure layer or a subsequent nanostructure layer includes alignment patterns embedded on and within its structure that are positioned to line up with the viewing ports. In a still further embodiment, alignment structures embedded into each layer can be viewed in combination with the alignment features of the new layer to allow various degrees of alignment with the alignment features of selected layers within the stack. Furthermore, focus and capture of alignment features of desired layers can be viewed in real time with the alignment features of said second layer or a subsequent layer as it is being aligned.

Variously, each nanostructure layer can contains set of holes extending through both structures. The holes in each added nanostructure layer can then be aligned to the other structures holes and attached or bonded, and then the new layer can be thinned.

It will be appreciated that the various steps of the fabrication methods described can be repeated to add new layers. It will also be appreciated that an embodiment of the invention generally comprises using an optical tool that allows alignment features from a processed side of a structure to be copied to the opposite non-processed side of the material. Accordingly, in this embodiment, top and bottom alignment features are precisely aligned with the alignment tool while in near contact and then attached or bonded after alignment. Each new layer of new nanomaterial can then be thinned after attachment or bonding. Furthermore, interconnects can be embedded in transparent vertical columns that allow radiant heat to be applied to the interconnects in vertical columns, wherein vertical interconnect elements can be heated to a degree that the electrical resistance between layers of the interconnect is lowered or the mechanical strength of the attachments of the segments of the vertical interconnects is increased. Furthermore, the vertical columns can be lined with a conductive and reflective material to produce a waveguide that can concentrate heat into the vertical interconnects.

Another aspect of the invention is a method wherein an existing stack is attached to a new layer that has nanostructure regions and precision alignment structures that are formed of a material transparent to short visible or ultraviolet light.

Another aspect of the invention is that each new nanolayer structure can be electrically tested before bonding and thinning to improve yield of the stacked formed.

Another aspect of the invention is that each nanostructure layer contained within a wafer can be tested and results mapped to allow selection of sets of mapped wafers for attachment or bonding to optimize yield of stacks produced.

Further embodiments and aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 illustrates prior art alignment of 3-d stacks.

FIG. 2 illustrates structures to be aligned according to various embodiments of the present invention.

FIG. 3 Illustrates details of the structures being aligned according to embodiments of the present invention.

FIG. 4 illustrates creation of a new stack layer to existing stack according to embodiments of the present invention.

FIG. 5 illustrates alignment features of structures on first and subsequent layers of 3-d stack according to the present invention.

FIG. 6 illustrates tethered structure alignment features according to the present invention.

FIG. 7 illustrates “Top to Bottom Alignment Transfer” according to the present invention.

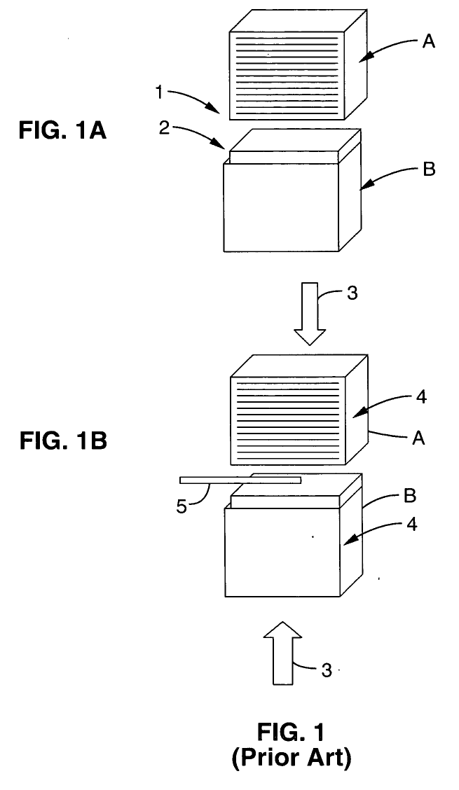

### DETAILED DESCRIPTION OF THE INVENTION

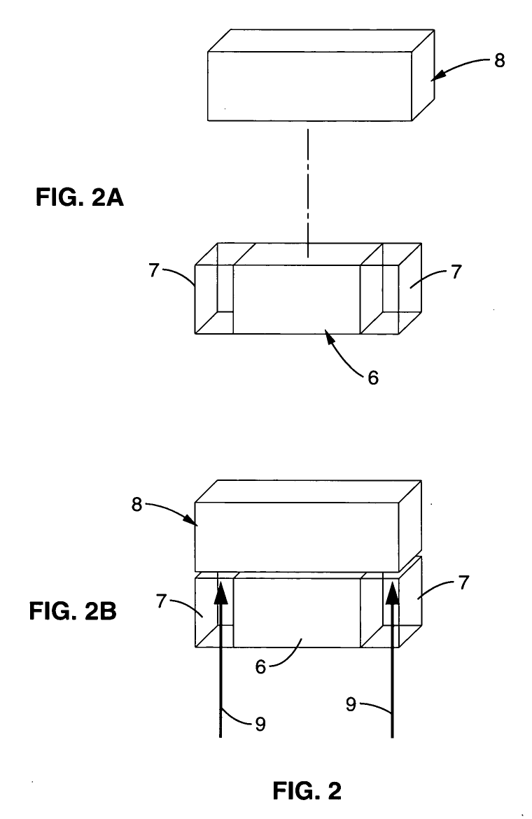

Referring more specifically to the drawings, for illustrative purposes the present invention is embodied in the methods and structures generally shown in FIG. 2 through FIG. 7.

An object of this invention is to provide methods and structures that allow alignment features of each new layer to be added to a 3-dimensional stack to be directly viewed and imaged while the structures are being held in near contact before bonding or otherwise attachment of the new layer to the existing stack. See FIG. 2 for an illustration of this basic concept that applies to the following sets of embodiments of this application. In one set of embodiments, an existing 3-dimensional stack structure will have defined optical pathways built into them that allow transmission of the short wavelengths of visible or ultraviolet light required for direct imaging of the new layers alignment structures while the two structures are held in near contact before the attachment process. The precision alignment is then accomplished by comparing and adjusting the position and angle of alignment features of the structure to be attached to alignment features of those on the existing stack. At least two such optical pathways are used to allow the structures to be aligned. In some cases an additional optical pathway must be provided to adjust the alignment to account for non parallelism of the surfaces of the structures being attached or bonded. These sets of embodiments are now described.

FIG. 2 illustrates the basic concepts of the present invention. Consider two structures, one of which is an existing 3-dimensional stack or handle or base layer that has at least two optical pathways built into it. This first structure will constitute Structure 6. The optical pathways are transparent to short wavelength visible or ultraviolet light capable of imaging submicron alignment patterns. The existing Structure (stack) 6 contains at least one set of alignment patterns embedded in its optical pathway. Alignment patterns are features imbedded into layers of micro- or nano-structures that are well known in the art. The optical pathways 7 are shown here at the two edges of Structure 6 for convenience. These optical pathways may be placed anywhere and more than two may be present.

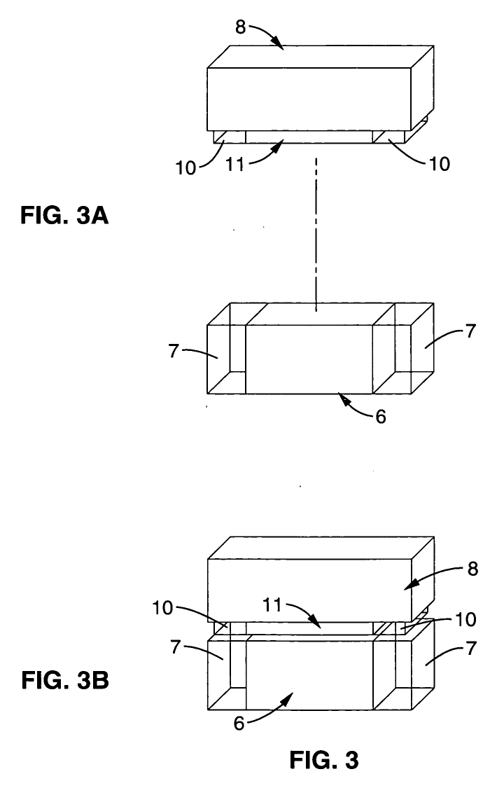

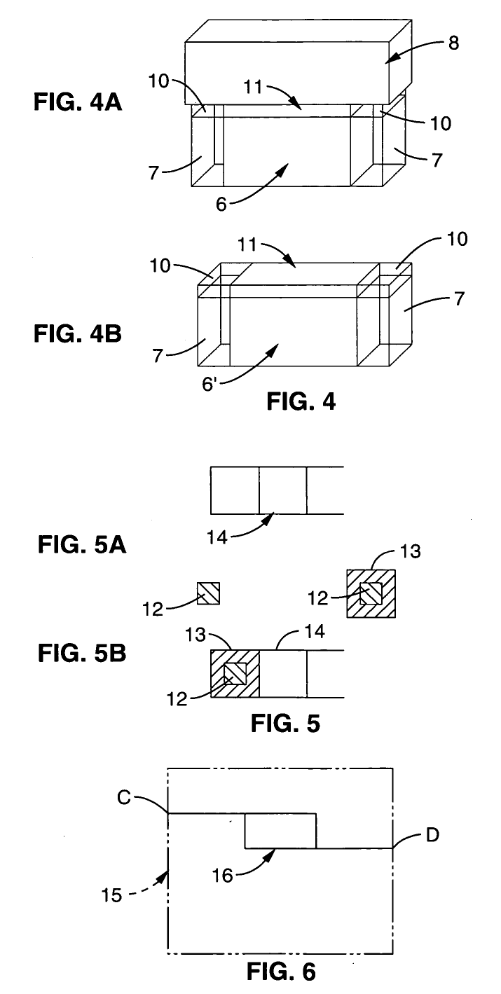

The other structure, that constitutes Structure 8, comprises a substrate and a processed bottom surface layer that has nanostructure regions and precision alignment structures built into each of the areas that will comprise a continuation of the optical pathways in the Structure 6 and will contain sets of alignment structures embedded in these optical pathways regions. The nanostructure regions are preferably formed of optimized material for the desired nanostructure (Si, Ge, GaAs, Strained Si, SiGe, Fe compounds for example). The remainder of the layer will be filed in with a deposited insulator such as SiO₂ that is compatible with the temperature constraints of the metallization scheme in the nanostructure and which is transparent to the desired wavelengths of light required for the optical resolution desired for the alignment. The entire surface will then be planarized. The alignment structures are built into these layers with the precision of the nanostructures produced on the layer For example, as of this date minimum feature sizes of <0.1 μm are in production and in the future these feature sizes are expected to become smaller. The features that comprise the opaque and transparent optical regions of Structure 8 are shown in detail in FIG. 3 and FIG. 4.

Once the nanostructure layer and associated alignment features are completed, Structure 6 and Structure 8 are held in near contact (near contact means held at a distance just large enough to not touch at any point on the two surfaces which is a function of the surface roughness of the processed surfaces) in preparation for bonding or otherwise attachment where an alignment tool is positioned to align the two structures by imaging the desired alignment features contained in Structure 6 to those of Structure 8. Once aligned, the two structures are brought into contact and bonded or otherwise attached to one another as shown in FIG. 2B where light 9 is shown passing through the optical pathways 7.

FIG. 3A illustrates more of the detail related to Structure 8. The bottom processed layer of Structure 8 contains transparent region 10 and opaque region 11 that contain processed nanostructures that are precisely aligned to alignment features processed into regions overlying optical pathways in the optical pathway in region 10. Structure 8 containing regions 10 and 11 will be brought into precise alignment with Structure 6 as shown in FIG. 3B.

FIG. 4A replicates the structure in FIG. 3B, where the precisely aligned structures have been bonded or otherwise attached. At this point, Structure 8 is thinned to a point that leaves only the new layer consisting of structures 10 and 11 attached to form a new Structure 6′ that contains this new layer shown in FIG. 4B. This new layer then comprises the new layer of nanostructure material, connection features between the new layer and the previous Structure 6, and an extension of the optical pathways such that this new Structure 6′ continues to provide the required optical pathways required to allow the layer addition procedure to be repeated in an iterative fashion to add as many new layer to the 3-dimensional stack as is desired. This procedure allows great flexibility in the alignment process since each layer of the 3-dimensional stack is built with these same transparent regions alignment features can be added into each layer in any desired manner to allow any combination of alignment preferences.

FIG. 5 illustrates an example of the flexibility of this alignment scheme. For example, as shown in FIG. 5A, if it is desired to align each new layer 12 to just the previous layer 13, then a pattern that builds up sequentially may be used. Or, if the new layer is only aligned to the first layer 14, then a pattern is generated where the first layer is adjacent to the new layer. Another alignment combination might be where the previous and first alignment are compared simultaneously with the current layers alignment as illustrated in FIG. 5B. Since each layers alignment marks are in different focal planes, a scheme can be used where images of each layers alignment marks are captured and then compared in real time with the current layers alignment.

Another embodiment shown in FIG. 6 that closely resembles the one just described follows all of the steps just described, but specifically calls for the optical pathways to be empty; that is only filled with whatever ambient atmosphere is contained within the packaged structures. In FIG. 6, the empty region is the region inside of the perimeter 15. For example, air or another gas such as nitrogen or even a vacuum might constitute the ambient atmosphere in the package. In this case Structure 7 of FIG. 3 and FIG. 4 is so modified to have the optical pathway empty as shown by the edges of empty space 15. In this case, any alignment patterns contained within the optical pathway would have to be tethered and could not be embedded in a transparent solid structure such as Sio₂. Structure 8 of FIG. 2 through FIG. 4 might then be constructed slightly differently than in the previous embodiment. Structure 8 of FIG. 2 through FIG. 4 might be constructed exactly as in the previous embodiment, except that after bonding or otherwise attachment and thinning the transparent material comprising the optical pathway would be removed, thus providing a new Structure 6′ as shown in FIG. 4 that has empty space except for the possibility of tethered alignment structures illustrated in FIG. 6 by Structure 16 with attachment point C and D. In the case that this Structure 6′ utilizes tethered alignment structures the empty optical path could be cleared before bonding and thinning and thus would be automatically emptied after the thinning process is completed. One application of this embodiment is for use of extremely precise alignment that might employee shorter wavelength radiation than can be transmitted through solid materials such as Sio₂. For example x-rays with extremely short wave length could be use for alignment with this embodiment.

### Other Embodiments

### Providing Improved Alignment Over the Prior Art

### Holes in the materials

A very simple method to provide alignment improvements over prior art methods would be to provide sets of holes that would extend entirely through both materials to be bonded or attached. Then, an alignment tool would be used to image and line up the set of holes while the two structures are held in near contact prior to bonding or otherwise attachment. For example, Structure 6 would be an existing stack as shown in FIG. 2 without the optical pathways shown in this figure and Structure 8 also in shown in FIG. 2 would host the new layer to be added to the stack . All nanostructures would then be formed in the faces of Structure 8 and aligned to the set of holes in this material. Again, the nanostructure regions are formed of optimized material for the desired nanostructure (Si, Ge, GaAs, Strained Si, SiGe, Fe compounds for example). After bonding or attachment, the Structure 8 is thinned to leave only an extended Structure 6′ as shown in FIG. 4B without the optical pathways 7 and 10 that contains the new layer. The procedure is then repeated in an iterative fashion for each new layer added to the Structure 6 of FIG. 2A with optical pathways removed.

### Top to Bottom Alignment Transfer

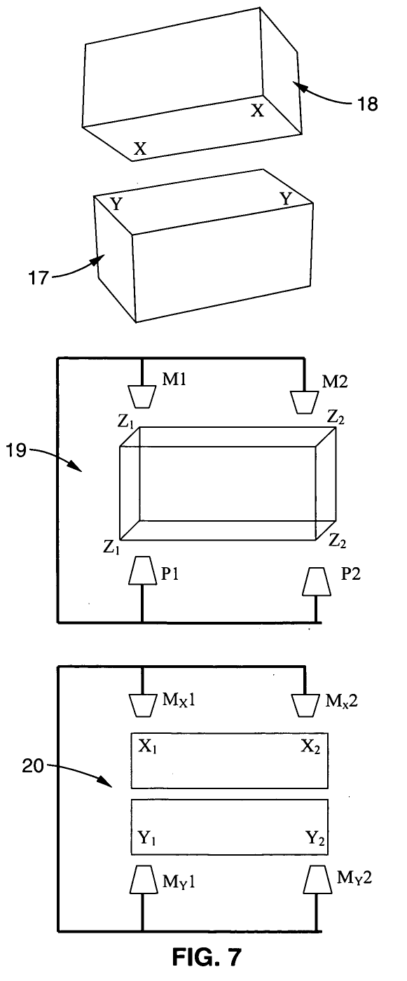

FIG. 7 illustrates structures and methods of transferring alignment patterns from a processed side of structures to the non processed side.

Consider a Structure 17 that has a nanostructure including a set of alignment features that are built onto one surface of the material. Consider an alignment tool 19, that is then able to image the alignment features on the opposite non-processed side of the structure in the precise location of the first alignment structure. Thus, this tool transfers the alignment features to the exposed side of Structure 17. Repeat this procedure on a Structure 18, then hold the two structures in near contact as shown in 20, align the exposed top and bottom alignment structures then bond or otherwise attach the structures together. The features of the two nanostructure layers will then be in precise alignment to the extent that the transferred alignment features are faithfully reproduced on the top and bottom exposed surfaces of the structures. Structure 17 with nanostructure on top face and alignment structures symbolically represented by the symbol Y. Structure 18 with nanostructure on bottom face and alignment structures symbolically represented by the symbol X An Optical Tool 19 is used for imaging alignment patterns Z₁ and Z₂ to locations Z₁′ and Z₂′ on the opposite face of this material. The accuracy of this placement of the alignment features represented symbolically by Z₁ and Z₂ to those symbolically represented by Z₁′ and Z₂′ is limited only by the placement of image microscopes M1 and M2 with respect to image projectors P1 and P2 and the degree of parallelism of the top and bottom surfaces of the structure. 2-dimensional rendition of the two structures with alignment patterns copied to top and bottom surfaces held in close proximity and ready for attachment or bonding. Before bonding, Structures 17 and 18 are precisely aligned in split field to an alignment data base as illustrated in Structure 20. When each pattern has been so adjusted the pair is attached or bonded. The 2-dimensional rendition of the two structures with alignment patterns copied to top and bottom surfaces held in close proximity and ready for attachment or bonding as shown in 20. Before bonding Structures 17 and 18 are precisely aligned in split field to an alignment data base. When each pattern has been so adjusted the pair is attached or bonded.

### Embedment of High Density Vertical Interconnects in a Region of Transparent Material

It may be advantageous to embed the high density vertical interconnects in a 3-dimensional stack into a transparent column that extends through the stack. It might be useful then to selectively radiant heat the vertical columns containing high density vertical interconnects to allow heat to fuse the interconnect elements of adjacent layers into connectors that have low electrical resistance and strong mechanical connection. In this case as each new layer of such transparent columns are formed the side walls of the columns can be lined with high reflectivity material such as aluminum that will direct the radiant light onto the interconnect segments. It may also be advantageous to shape these columns into rectangular structures that constitute waveguides that couple microwave or other radiation into the cavity to again selectively heat the conducting elements of contained within the vertical cavity.

### Yield Enhancement Methods and Structures for the 3-Dimensional Stacks

Yield considerations must be addressed when considering the formation of stacks with face to face bonded wafers and chips. The solution to such problems may be considered as follows:

First, well known methods of redundancy and error correction, error detection can be applied to help in the solution to this problem. This solution is especially applicable to stacked memories since such error detection, error correction as well as redundancy is easily implemented. Such methods may also be applied to non memory structures, but the methods, while known, are more complex.

Each layer can be tested before being added to a stack. At the chip level this is very straight forward. At the wafer level each chip can be tested and the result mapped into a data base. This information can then be used to choose sets or wafers most suitable from a yield standpoint to be added together into a stack.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art. In the appended claims, reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

1. A method for forming a stack of nanostructure layers, comprising:
a) forming a plurality of viewing ports in a first nanostructure layer through which an alignment pattern on a second nanostructure layer is visible when said first and second nanostructure layers are held in near contact before attachment;
b) aligning said second nanostructure layer with said first nanostructure layer by viewing said alignment pattern through said viewing ports; and
c) attaching said second nanostructure layer to said first nanostructure layer after alignment with said first nanostructure.

2. A method as recited in claim 1, further comprising:
d) extending said viewing ports through said attached second nanostructure layer;
e) aligning a third nanostructure layer with said second nanostructure layer by viewing an alignment pattern on said third nanostructure layer through said extended viewing ports; and
f) attaching said aligned third nanostructure layer to said second nanostructure layer.

3. A method as recited in claim 1, wherein said alignment patterns are viewed under short wavelengths of visible ultraviolet light.

4. A method as recited in claim 1, wherein the viewing ports allow imaging of submicron alignment features.

5. A method as recited in claim 1, wherein said layers are attached using an attachment method selected from the group consisting essentially of fusion bonding, low temperature fusion bonding, low temperature plasma assisted fusion bonding, adhesive bonding, anodic bonding, and thermal compression metal to metal bonding.

6. A method as recited in claim 1 wherein precision alignment features are included in each layer that are precisely aligned to the nanostructure of the layer with feature sizes and alignment that is that of the nanostructure itself.

7. (canceled)

8. A method as recited in claim 1, wherein intervening layers of heat sinks, RF shields, or various control function circuits needed to control the proper operation of a stacked system of nanostructure layers are interspersed throughout the stack and each layer with viewing ports that allow the optical viewing ports to extend through the layers and allow the layers to be precision aligned to the nanostructures in the stack.

9. A method as recited in claim 1, further comprising thinning each nanostructure layer added to the stack using any method of thinning a processed nanostructure layer.

10. A method as recited in claim 1, wherein at least one said nanostructure layer includes extended viewing regions comprising embedded alignment features in a SiO₂ layer.

11. (canceled)

12. A method as recited in claim 1, wherein after attachment of an added nanostructure layer the added nanostructure layer is thinned to leave (a) the nanostructure layer, and (b) connection features between the added layer and previous layers.

13. A method as recited in claim 1, wherein said viewing ports form an extended optical pathway that is empty except for alignment features.

14.-16. (canceled)

17. A method as recited in claim 1, wherein said alignment pattern comprises alignment features are tethered to structures adjacent to optical pathways formed by the viewing ports.

18. A method as recited in claim 1, wherein alignment features in optical pathways formed by the viewing ports can pass very short wavelengths of light that will not pass through SiO₂ or other solid materials.

19. A method as recited in claim 1, wherein optical pathways formed by said view ports will pass x-rays.

20. A method as recited in claim 1, further comprising:
d) providing a base layer;
e) forming a set of viewing ports in said base layer;
f) attaching said first nanostructure layer to said base layer;
g) thinning said first nanostructure layer; and
h) extending said viewing ports through said first nanostructure layer.

21. A method as recited in claim 1, wherein each nanostructure layer to be aligned with said first nanostructure layer or a subsequent nanostructure layer includes alignment patterns embedded on and within its structure that are positioned to line up with said viewing ports.

22. A method as recited in claim 1, wherein alignment structures embedded into each layer can be viewed in combination with the alignment features of the new layer to allow various degrees of alignment with the alignment features of selected layers within the stack.

23. A method as recited in claim 1, wherein focus and capture of alignment features of desired layers can be viewed in real time with the alignment features of said second layer or a subsequent layer as it is being aligned.

24. A method as recited in claim 1, wherein each nanostructure layer contains sets of holes extending through both structures.

25. A method as recited in claim 1, wherein each added nanostructure layer holes are aligned to the other structures holes and attached or bonded and then the new layer is thinned.

26.-32. (canceled)
